(19) United States
(12) Patent Application Publication
(10) Pub. No.: US 2026/0123026 A1
(43) Pub. Date: Apr. 30, 2026

(54) SIC TRENCH MOSFET CELL WITH AN EMBEDDED SUPPER BARRIER RECTIFIER

(71) Applicant: Nami MOS CO., LTD., New Taipei City (TW)

(72) Inventors: Fu-Yuan HSIEH, New Taipei City (TW); Lin XU, Shanghai (CN)

(21) Appl. No.: 18/925,551

(22) Filed: Oct. 24, 2024

(51) Int. Cl. H01L 29/78; H01L 29/06; H01L 29/16; H01L 29/40; H01L 29/417

(52) U.S. Cl. CPC H10D 84/146; H10D 30/668; H10D 62/111; H10D 62/127; H10D 62/8325; H10D 64/117; H10D 64/252

(57) ABSTRACT

A SiC power device cell having a first gate channel region of a SiC MOSFET formed along a first gate trench sidewall of a gate trench connecting to a first source region, and a second gate channel region of a SiC SBR which is a MOS channel diode formed along the gate trench bottom connecting to a second source region to inactivate a parasitic body diode for turn-off switching loss reduction. A P-shield region and a second source region surrounding a second gate trench sidewall and a portion of the gate trench bottom to form the second gate channel region and to reduce the gate oxide electric field.

### FIELD OF THE INVENTION

This invention relates generally to a unit cell structure of a semiconductor device, and more particularly, to integrate a novel SiC Metal Oxide Semiconductor Field Effect Transistor (MOSFET) and a SiC Super Barrier Rectifier (SBR) as a MOS-Channel diode (MCD) into a same gate trench structure.

### BACKGROUND OF THE INVENTION

Because of the faster switching speed, higher temperature operation, and lower switching loss, SiC MOSFETs are very promising to replace Si super junction (SJ) MOSFETs and Si insulated gate bipolar transistors (IGBTs). However, A parasitic PIN body diode of SiC MOSFETs has a relatively higher turn-on voltage (˜3 V) than its Si MOSFET counterpart (˜0.7 V), owing to the wide band gap properties, which deteriorates reverse recovery characteristics. As a result, external Schottky barrier diodes (SBDs) are normally used in the power modules to inactivate a parasitic PIN diode. However, it was found that the parasitic inductance between the MOSFET and the external SBD has a great effect on the conduction power loss.

Various integrated devices are suggested and demonstrated to improve the characteristics of the parasitic PIN body diode in SiC MOSFETs. Among them, integrating with a Schottky Barrier Diode (SBD) or a Junction barrier diode (JBSD) is widely adopted. However, a high-temperature reverse leakage current of the SBD is much larger than that of the parasitic PIN diode.

Therefore, there is still a need in the art of SiC MOSFETs design and fabrication, to provide a novel cell structure, device configuration and manufacturing process that making SiC trench MOSFETs have a lower on-resistance and a lower switching loss.

### SUMMARY OF THE INVENTION

The present invention discloses a SiC Power device comprising a SiC MOSFET and a SiC SBR disposed in each unit cell having a gate trench structure comprising: a first gate channel region of the SiC MOSFET formed between a first body region and a second source region along a first gate trench sidewall, and a second gate channel region of the SiC SBR formed between a P-shield region as a second body region along a bottom region of the gate trench; the SiC MOSFET has a first gate oxide, and the SiC SBR has a second gate oxide with a thickness thinner than that of the first gate oxide; the SiC SBR has a channel length shorter than that of the SiC MOSFET; the second body region and the second source region surrounding a second gate trench sidewall, and a portion of the bottom region of the gate trench aside the second gate trench sidewall to form the second channel region; The first PS region connecting to a source metal through a first P body region to reduce the gate oxide electric field.

According to one aspect, the invention features a SiC power device further comprising a first gate electrode of the SiC MOSFET and a second gate electrode of the SiC SBR disposed in the gate trench side by side; the first gate electrode laterally isolated from the epitaxial layer by a first gate oxide of the SiC MOSFET on the first gate trench sidewall, and the second gate electrode vertically isolated from the epitaxial layer by a second gate oxide of the SiC SBR on a bottom region of the gate trench, wherein the second gate oxide has a thickness less than that of the first gate oxide; and the second gate electrode shorted to a source metal through a gate contact of the SiC SBR.

According to another aspect, the invention features a SiC power device further comprising a gate electrode disposed in an upper portion of the gate trench, and a shielded gate electrode disposed below the gate electrode and isolated from the gate electrode by an inter-poly oxide (IPO) layer; the gate electrode as a first gate electrode laterally isolated from the epitaxial layer by a first gate oxide of the SiC MOSFET on the first gate trench sidewall, and the shielded gate electrode as a second gate electrode vertically isolated from the epitaxial layer with a second gate oxide of the SiC SBR on the bottom region of the gate trench, wherein the second gate oxide has a thickness less than that of the first gate oxide; and the shielded gate electrode shorted to a source metal through a shielded gate contact of the SiC SBR.

According to another aspect, the invention features a SiC power device further comprising a shielded gate electrode disposed in a middle of the gate trench, and a pair of split gate electrodes as the first gate electrodes disposed surrounding an upper portion of the shielded gate electrode; the first gate electrodes laterally isolated from the epitaxial layer with a first gate oxide of the SiC MOSFET on the first gate trench sidewall, and the shielded gate electrode as the second gate electrode vertically isolated from the epitaxial layer with a second gate oxide of the SiC SBR on the bottom region of the gate trench, wherein the second gate oxide has a thickness less than that of the first gate oxide; and the shielded gate electrode shorted to a source metal through a shielded gate contact of the SiC SBR.

According to another aspect, the invention features a SiC power device further comprising a super junction (SJ) structure comprising a P column (PC) region of a second conductivity type. At least two sidewall P-shield (SPS) regions of a second conductivity type facing each other with a doping concentration higher than that of the PC region, adjoining the PC region; and a Junction Field Effect Transistor (JFET) region of a first conductivity type formed between the two adjacent SPS regions with a doping concentration higher than that of the epitaxial layer.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description serve to explain the principles of the invention. In the drawings:

FIG. 1 is a top view of a preferred embodiment for a trench semiconductor power device with stripe cells layout according to the present invention.

FIG. 2A is a cross-sectional view showing a preferred A1-A1′ cross section of FIG. 1 with two gate electrodes disposed in the gate trench side by side according to the present invention.

FIG. 2B is a cross-sectional view showing a preferred B1-B1′ cross section of FIG. 1 representing the gate electrode contact area of the SiC SBR according to the present invention.

FIG. 2C is a cross-sectional view showing a preferred C1-C1′ cross section of FIG. 1 representing the gate electrode contact area of the SiC MOSFET according to the present invention.

FIG. 2D is a cross-sectional view showing another preferred A1-A1′ cross section of FIG. 1 with a current spreading implant (CSI) region below a bottom of the gate trench according to the present invention.

FIG. 2E is a cross-sectional view showing another preferred A1-A1′ cross section of FIG. 1 with a third PS region adjacent to the second source region according to the present invention.

FIG. 2F is a cross-sectional view showing another preferred A1-A1′ cross section of FIG. 1 with an N type buffer source region below the first and second source regions according to the present invention.

FIG. 3A is a cross-sectional view showing another preferred A1-A1′ cross section of FIG. 1 with a SJ structure comprising a P column region according to the present invention.

FIG. 3B is a cross-sectional view showing another preferred A1-A1′ cross section of FIG. 1 with an additional N buffer layer sandwiched between the N+ substrate and the PC regions according to the present invention.

FIG. 3C is a cross-sectional view showing another preferred A1-A1′ cross section of FIG. 1 with a JFET region formed between the two adjacent SPS regions according to the present invention.

FIG. 4A is a cross-sectional view showing another preferred A1-A1′ cross section of FIG. 1 representing an IGBT with a P+ substrate according to the present invention.

FIG. 4B is a cross-sectional view showing another preferred A1-A1′ cross section of FIG. 1 representing an IGBT with a plurality of alternating P+ and N+ regions in the P+ substrate according to the present invention.

FIG. 5A is a cross-sectional view showing another preferred A1-A1′ cross section of FIG. 1 with planar contacts according to the present invention.

FIG. 5B is a cross-sectional view showing another preferred A1-A1′ cross section of FIG. 1 with planar contacts and a CSI region below a bottom of the gate trench according to the present invention.

FIG. 6 is a top view of another preferred embodiment for a trench semiconductor power device with stripe cells layout according to the present invention.

FIG. 7A is a cross-sectional view showing a preferred A2-A2′ cross section of FIG. 6 with a shielded gate electrode disposed below a gate electrode in the gate trench according to the present invention.

FIG. 7B is a cross-sectional view showing another preferred A2-A2′ cross section of FIG. 6 with a CSI region below a bottom of the gate trench according to the present invention.

FIG. 7C is a cross-sectional view showing a preferred B2-B2′ cross section of FIG. 6 representing the shielded gate electrode contact area according to the present invention.

FIG. 7D is a cross-sectional view showing another preferred A2-A2′ cross section of FIG. 6 with an N type buffer source region below the first and second source regions according to the present invention.

FIG. 8A is a cross-sectional view showing another preferred A2-A2′ cross section of FIG. 6 with a SJ structure comprising a P column region according to the present invention.

FIG. 8B is a cross-sectional view showing another preferred A2-A2′ cross section of FIG. 6 with a JFET region formed between the two adjacent SPS regions according to the present invention.

FIG. 8C is a cross-sectional view showing another preferred A2-A2′ cross section of FIG. 6 with an additional N buffer layer sandwiched between the N+ substrate and the PC regions according to the present invention.

FIG. 9A is a cross-sectional view showing another preferred A2-A2′ cross section of FIG. 6 representing an IGBT with a P+ substrate according to the present invention.

FIG. 9B is a cross-sectional view showing another preferred A2-A2′ cross section of FIG. 6 representing an IGBT with a plurality of alternating P+ and N+ regions in the P+ substrate according to the present invention.

FIG. 10A is a cross-sectional view showing another preferred A2-A2′ cross section of FIG. 6 with planar contacts according to the present invention.

FIG. 10B is a cross-sectional view showing another preferred A2-A2′ cross section of FIG. 6 with planar contacts and a CSI region below a bottom of the gate trench according to the present invention.

FIG. 11A is a cross-sectional view showing another preferred A2-A2′ cross section of FIG. 6 with a pair of split gate electrodes surrounding an upper portion of the shielded gate electrode in the gate trench according to the present invention.

FIG. 11B is a cross-sectional view showing another preferred A2-A2′ cross section of FIG. 6 with planar contacts according to the present invention.

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

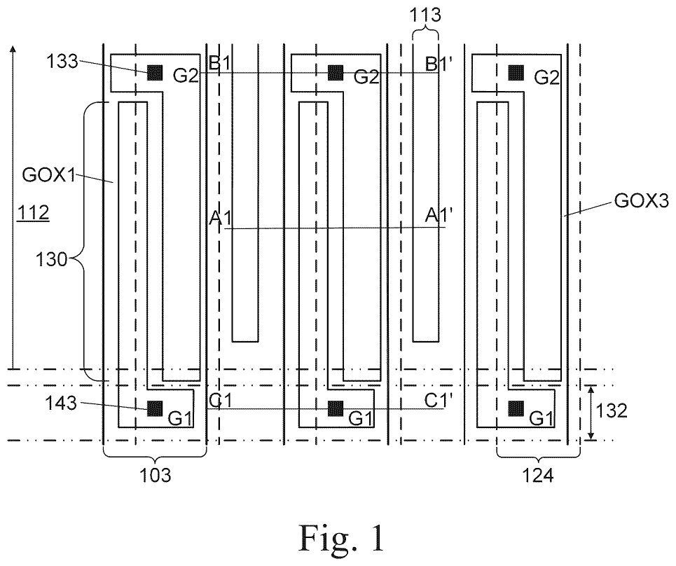

Please refer to FIG. 1 for a top view of a SiC power device having an asymmetric gate trench structure with stripe cells layout. The trenched source contacts 113 are disposed between the adjacent gate trenches 103, and a first P-shield (PS) region 124 is grounded to a source metal 112 through the trenched source contacts 113. According to this invention, a MOSFET channel region 130 is formed along a first trench sidewall of the gate trench 103 with a first gate oxide GOX1 and two gate electrodes 105 and 115 are formed in the gate trench 103, wherein the first gate electrode 105 is shorted to a gate metal runner 132 through a gate contact (G1, as illustrated) 143 of the SiC MOSFET and the second gate electrode 115 is shorted to a source metal 112 through a gate contact (G2, as illustrated) 133 of the SiC SBR.

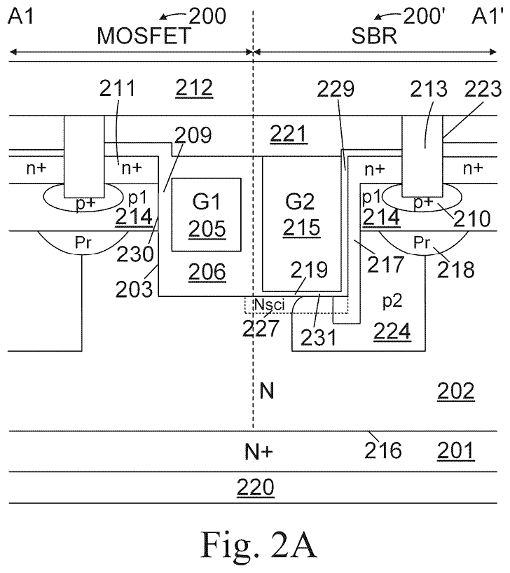

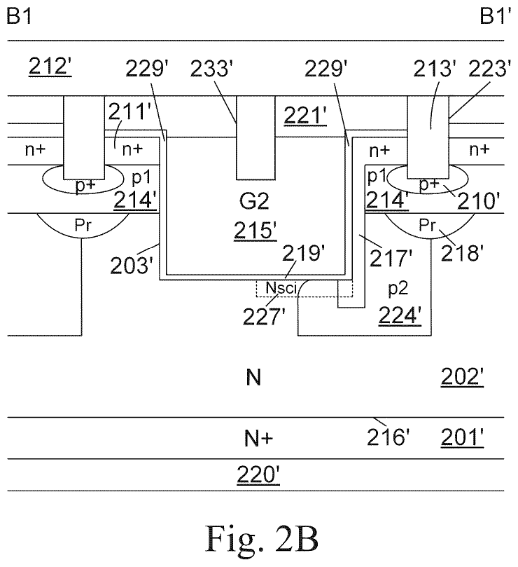

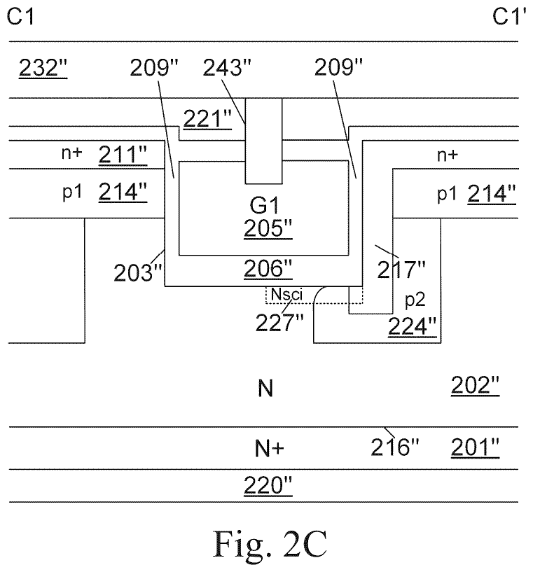

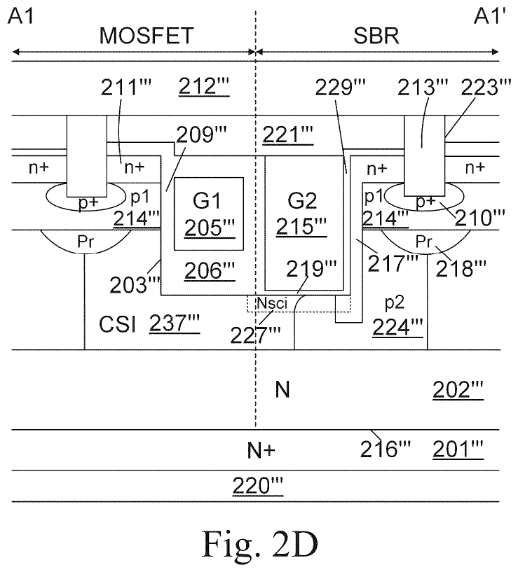

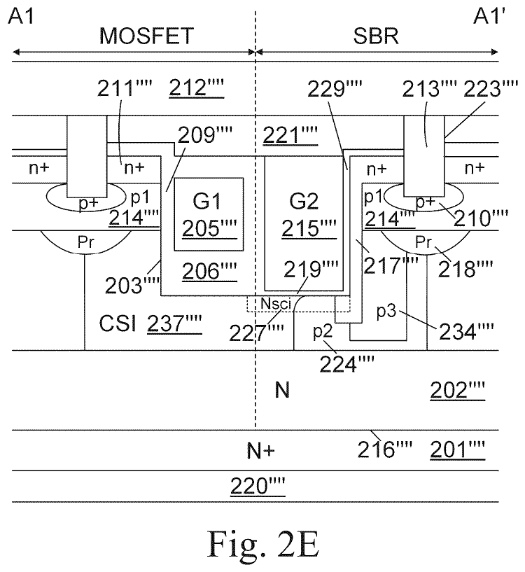

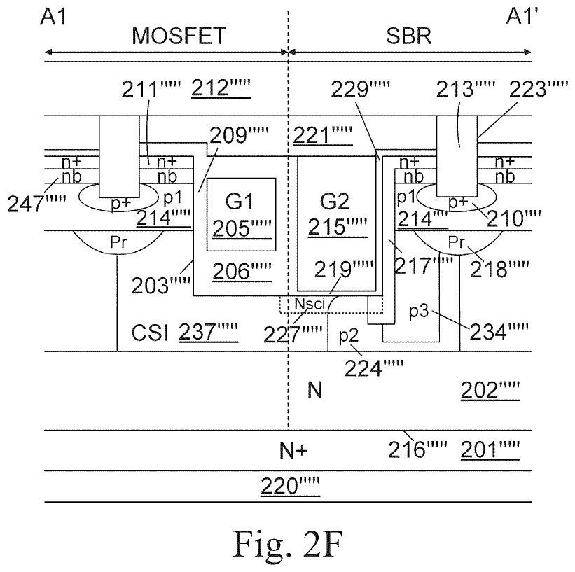

Please refer to FIG. 2A for a preferred embodiment of A1-A1′ cross-sectional view of FIG. 1 wherein an N-channel SiC MOSFET 200 and a SiC SBR 200′ are integrated in a single cell which is formed on an N+ substrate 201 with a less doped N type epitaxial layer 202 extending thereon, wherein the N+ substrate is coated with a back metal 220 on rear side as a drain metal. Inside the N type epitaxial layer 202, a plurality of gate trenches are formed vertically downward from a top surface of the N type epitaxial layer 202 and not reaching the common interface 216 between the N type epitaxial layer 202 and the N+ substrate 201. Inside each of the gate trenches 203, a first gate electrode (G1, as illustrated) 205 of the SiC MOSFET 200 and a second gate electrode (G2, as illustrated) 215 of the SiC SBR 200′ are formed side by side. The first gate electrode 205 is laterally isolated from the adjacent epitaxial layer by a first gate oxide (GOX1) 209 of the SiC MOSFET 200 on the first gate trench sidewall, and vertically isolated from the adjacent epitaxial layer by a first insulating film 206 on a bottom region of the gate trench 203 with a thickness greater than that of the first gate oxide 209. The second gate electrode 215 is vertically isolated from the adjacent epitaxial layer by a second gate oxide (GOX2) 219 of the SiC SBR 200′ on a bottom of the gate trench 203, and laterally isolated from the adjacent epitaxial layer by a third gate oxide (GOX3) of the SiC SBR 200′ on the second gate trench sidewall, wherein the second gate oxide (GOX2) 219 has a thickness thinner than that of the first gate oxide (GOX1) 209, and the second gate trench sidewall is opposite to the first gate trench sidewall. A SiC MOSFET channel region 230 as a first channel region is formed along a first trench sidewall of the gate trench 203, and a SiC SBR channel region 231 as a second channel region is formed along a bottom region of the gate trench 203. In the MOSFET 200, a p1 body region 214 having a first n+ source region 211 thereon is extending in an upper portion of the N type epitaxial layer 202 and surrounding the first gate electrodes 205 padded by the first gate oxide 209, wherein a first channel region is formed between the p1 body region 214 and the first n+ source region 211 along the first gate trench sidewall; while in the SBR 200′, a short channel implant (Nsci, as illustrated) region 227 is formed along a portion of the bottom region of the gate trench below the second gate electrode 215 surrounding the SiC SBR channel region 231, a p2 body region 224 as the first P-shield (p2, as illustrated) region and a second n+ source region 217 are formed surrounding a second gate trench sidewall and overlapping a portion of the bottom region of the gate trench adjacent to the second gate trench sidewall, wherein the p2 body region 224 has a doping concentration lower than that of the p1 body region 214. The second channel region 231 is formed between the p2 body region 224 and the second n+ source region 217 with a channel length shorter than that of the first channel region 230. An interlayer dielectric film 221 is stacked on the epitaxial layer 202, and a source metal 212 is formed onto the interlayer dielectric film 221. The p1 and p2 body regions 214 and 224, and the first and second n+ source regions 211 and 217 are shorted to the source metal 212 through a plurality of trenched contacts 223 filled with contact metal plugs and metal barriers 213 and surrounded by p+ heavily doped regions 210 around bottoms underneath the first and second n+ source regions 211 and 217, wherein the p2 body region 224 as the first PS region is connected to the source metal 212 for the gate oxide electric field reduction Moreover, another p type gate oxide electric field reducing (Pr, as illustrated) regions 218 are formed as second P-shield regions, adjoining lower surfaces of the p1 body regions 214 and being spaced apart from the gate trenches 203.

Please refer to FIG. 2B for a preferred B1-B1′ cross-sectional view of FIG. 1 with a new and improved device structure, which is a cross-sectional view of the gate electrode contact area of the SiC SBR. In the present invention, a second gate electrode (G2, as illustrated) 215′ is formed in each of the gate trenches 203′ and vertically isolated from the N type epitaxial layer 202′ by a second gate oxide film (GOX2) 219′ on a bottom region of the gate trench 203′ and laterally isolated from the N type epitaxial layer 202′ by a third gate oxide film (GOX3) 229′ on the gate trench sidewall, and furthermore, the second gate electrode 215′ is connected to a source metal 212′ through a trenched contact 233′.

Please refer to FIG. 2C for a preferred C1-C1′ cross-sectional view of FIG. 1 with a new and improved device structure, which is a cross-sectional view of the gate electrode contact area of the SiC MOSFET. In the present invention, a first gate electrode (G1, as illustrated) 205″ is formed in an upper portion of each of the gate trenches 203″ and isolated from the N type epitaxial layer 202″ by a first gate oxide film (GOX1) 209″ along a trench sidewall and a first insulating film 206″ on a bottom of the gate trench 203″, wherein the first gate oxide film 209″ has a thinner thickness than the first insulating film 206″, and furthermore, the first gate electrode 205″ is connected to a gate metal runner 232″ through a trenched contact 243″.

Please refer to FIG. 2D for another preferred A1-A1′ cross-sectional view of FIG. 1 with a new and improved device structure. The SiC power device has a similar structure to FIG. 2A, except that the present invention further comprises an N type current spreading implant (CSI, as illustrated) region 237′″ formed below a bottom region of the gate trench 203′″ and between the two adjacent PS regions 224′″, wherein the CSI region 237′″ has a doping concentration higher than that of the N type epitaxial layer 202′″.

Please refer to FIG. 2E for another preferred A1-A1′ cross-sectional view of FIG. 1 with a new and improved device structure. The SiC power device has a similar structure to FIG. 2D, except that the present invention further comprises a third P-shield (p3, as illustrated) region 234″″ of a second conductivity type adjacent to the second n+ source region 217″″, wherein the third P-shield region 234″″ has a doping concentration higher than that of the first PS region 224″″.

Please refer to FIG. 2F for another preferred A1-A1′ cross-sectional view of FIG. 1 with a new and improved device structure. The SiC power device has a similar structure to FIG. 2E, except that the present invention further comprises an N type buffer source region 247′″″ below the first and second source regions 211′″″ and 217′″″ with a doping concentration lower than that of the first and second source regions 211′″″ and 217′″″ to increase the source resistance for positive temperature coefficient improvement.

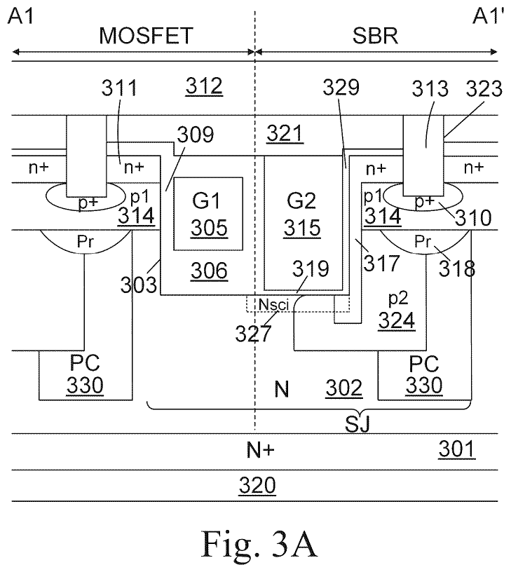

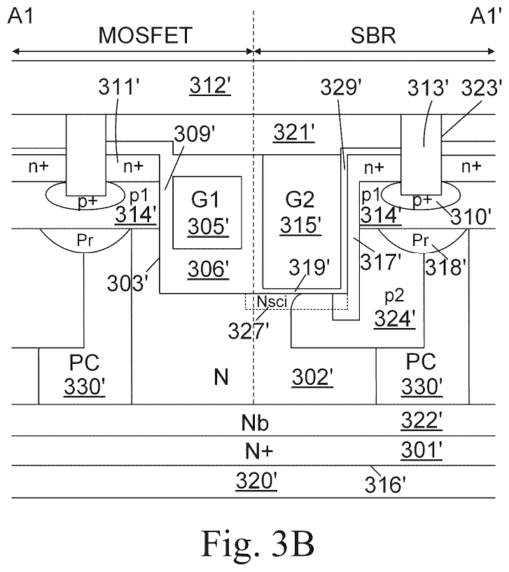

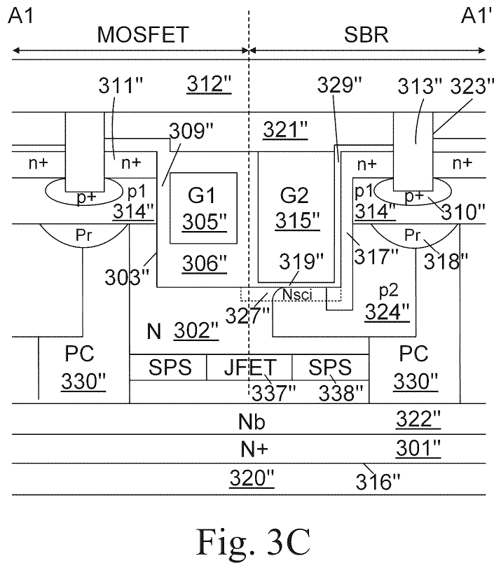

Please refer to FIG. 3A for another preferred A1-A1′ cross-sectional view of FIG. 1 with a new and improved device structure. The SiC power device has a similar structure to FIG. 2A, except that the present invention further comprises P column (PC, as illustrated) regions 330 of a second conductivity type formed adjoining bottom surfaces of the p1 and p2 regions 314 and 324 above the N+ substrate 301. A super junction (SJ, as illustrated) structure is thus generated by the N type epitaxial layer 302 and the PC region 330.

Please refer to FIG. 3B for another preferred A1-A1′ cross-sectional view of FIG. 1 with a new and improved device structure. The SiC power device has a similar structure to FIG. 3A, except that the present invention further comprises an additional N buffer layer (Nb, as illustrated) 322′ with a resistivity Rb sandwiched between the N+ substrate 301′ and the PC regions 330′, wherein Rb is higher than a resistivity R of the N type epitaxial layer 302′.

Please refer to FIG. 3C for another preferred A1-A1′ cross-sectional view of FIG. 1 with a new and improved device structure. The SiC power device has a similar structure to FIG. 3B, except that the present invention further comprises two sidewall P-shield (SPS, as illustrated) regions 338″ of a second conductivity type facing each other horizontally adjoining the P column (PC, as illustrated) regions 330″ with a doping concentration higher than that of the PC regions 330″, and a Junction Field Effect Transistor (JFET, as illustrated) region 337″ of a first conductivity type is formed between the two SPS regions 338″ with a doping concentration higher than that of the N type epitaxial layer 302″.

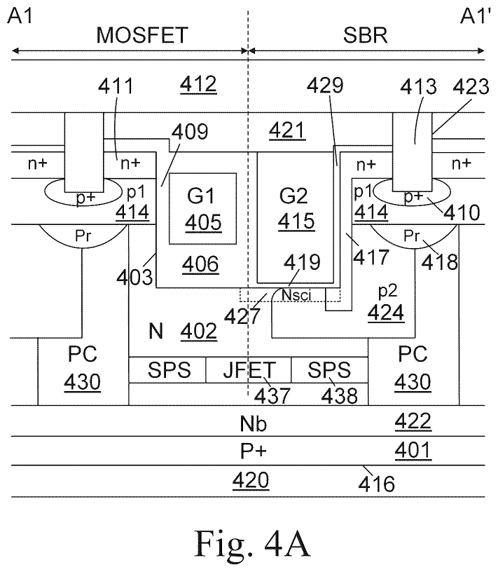

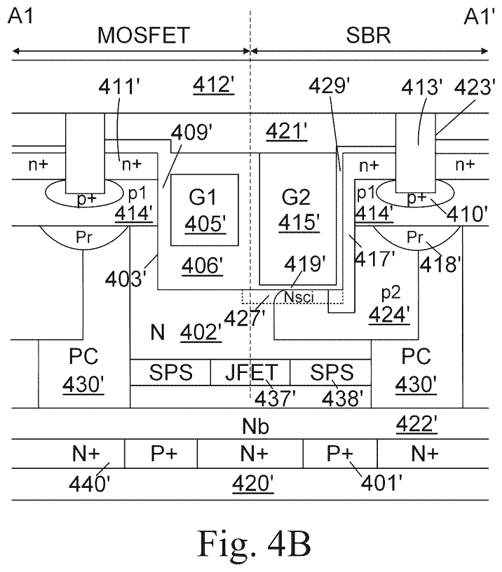

Please refer to FIG. 4A for another preferred A1-A1′ cross-sectional view of FIG. 1 with a new and improved device structure. The SiC power device has a similar structure to FIG. 3C, except for the different substrate. In this invention, the SiC power device is formed on a P+ substrate 401, and the N buffer layer (Nb, as illustrated) 422 sandwiched between the P+ substrate 401 and the PC regions 430 has a resistivity Rb lower than a resistivity R of the N type epitaxial layer 402.

Please refer to FIG. 4B for another preferred A1-A1′ cross-sectional view of FIG. 1 with a new and improved device structure. The SiC power device has a similar structure to FIG. 4A, except that, the SiC power device in FIG. 4B further comprises a plurality of heavily doped N+ regions 440′ in the P+ substrate 401′ to form a plurality of alternating P+ and N+ regions in the substrate.

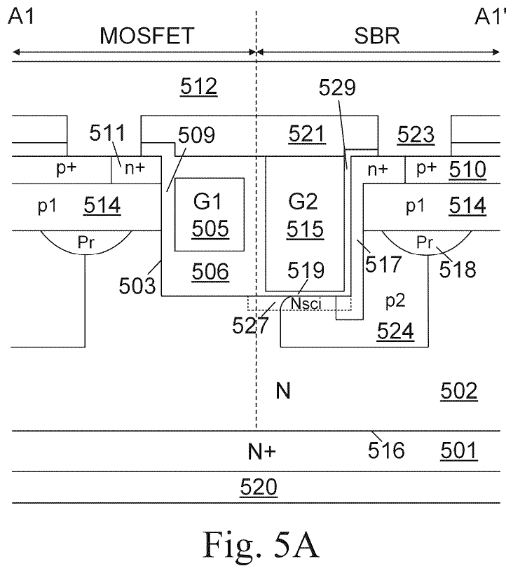

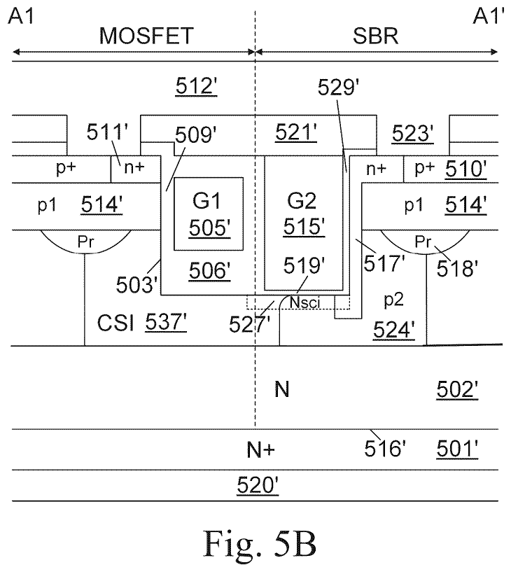

Please refer to FIG. 5A for another preferred A1-A1′ cross-sectional view of FIG. 1 with a new and improved device structure. The SiC power device has a similar structure to FIG. 2A, except that the source contacts 523 in the present invention are planar contacts.

Please refer to FIG. 5B for another preferred A1-A1′ cross-sectional view of FIG. 1 with a new and improved device structure. The SiC power device has a similar structure to FIG. 2D, except that the source contacts 523′ in the present invention are planar contacts.

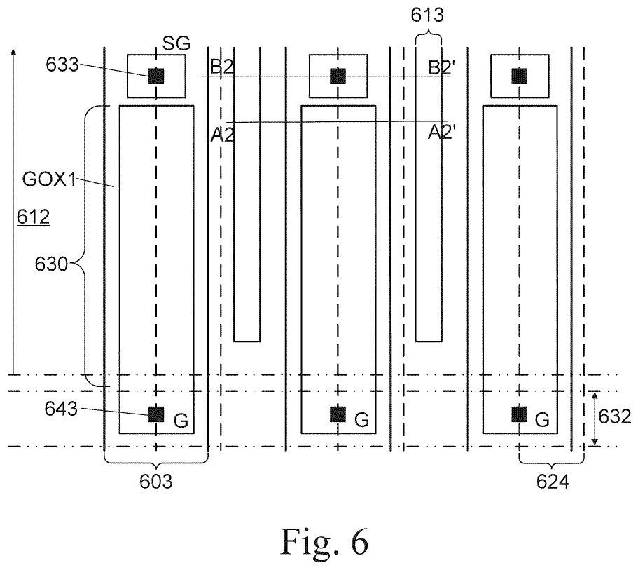

Please refer to FIG. 6 for another top view of a SiC power device having an asymmetric gate trench structure with stripe cells layout. The SiC power device has a similar structure to FIG. 1, except for the different gate structure in the stripe gate trench 603. According to this invention, a MOSFET channel region 630 is formed along a first sidewall of the gate trench 603 with a gate oxide GOX1, and two electrodes comprising a gate electrode and a shielded gate electrode are formed in the gate trench 603, wherein the gate electrode as a first gate electrode is shorted to a gate metal runner 632 through a first gate contact (G, as illustrated) 643 and the shielded gate electrode as a second gate electrode is shorted to a source metal 612 through a shielded gate contact (SG, ss illustrated) 633.

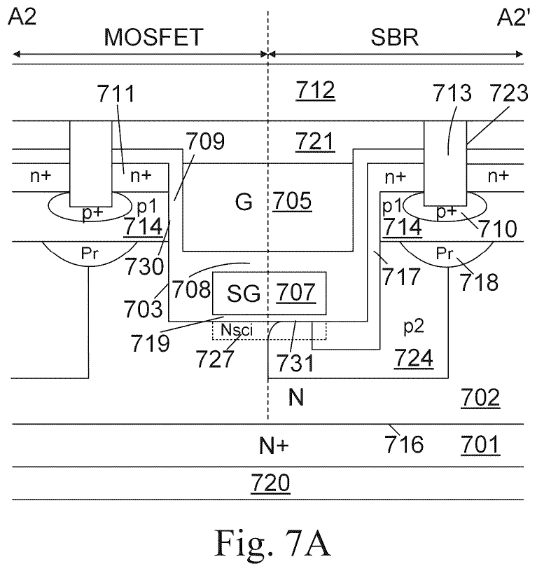

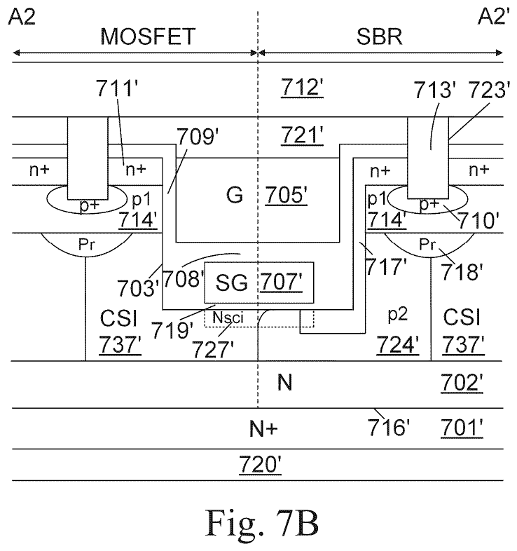

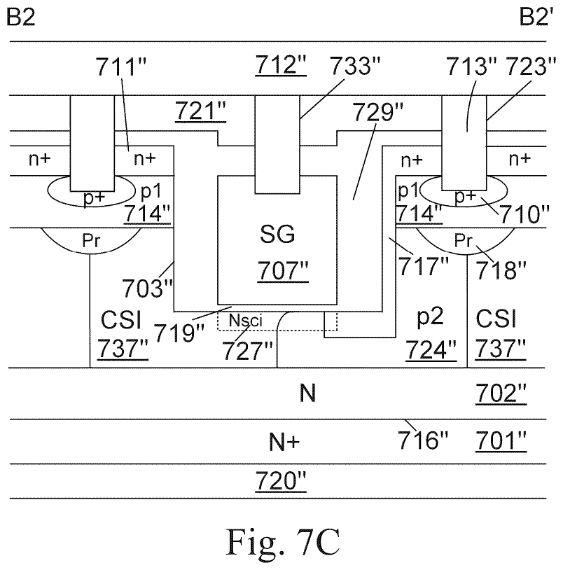

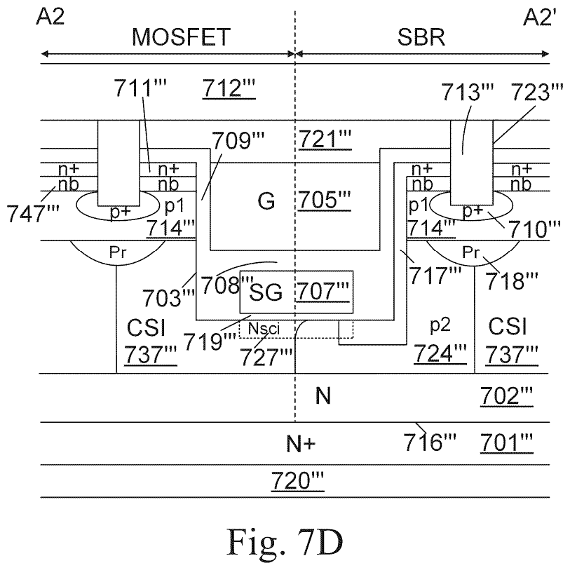

Please refer to FIG. 7A for a preferred A2-A2′ cross-sectional view of FIG. 6 with a new and improved device structure. The SiC power device has a similar structure to FIG. 2A, except for the different shielded gate structure in the gate trench 703. In the present structure, inside each of the gate trenches 703, a shielded gate electrode (SG, as illustrated) 707 is disposed in a lower portion of the gate trench below a single gate electrode (G, as illustrated) 705 in an upper portion, and the gate electrode 705 is laterally isolated from the adjacent epitaxial layer with a first gate oxide (GOX1) 709 on the gate trench sidewall, the shielded gate electrode 707 is vertically isolated from the adjacent epitaxial layer with a second gate oxide (GOX2) 719 on a bottom of the gate trench 703, wherein the second gate oxide 719 has a thinner thickness than the first gate oxide 709. Meanwhile, the shielded gate electrode 707 and the gate electrode 705 is insulated from each other by another insulating film 708 as an inter-poly oxide (IPO) layer. According to this invention, a SiC MOSFET channel region 730 as a first channel region is formed along a first trench sidewall of the gate trench 703, and a SiC SBR channel region 731 as a second channel region is formed along a bottom region of the gate trench 703 below the shielded gate electrode 707.

Please refer to FIG. 7B for another preferred A2-A2′ cross-sectional view of FIG. 6 with a new and improved device structure. The SiC power device has a similar structure to FIG. 7A, except that the present invention further comprises an N type current spreading implant (CSI, as illustrated) region 737′ formed below a bottom of the gate trench 703′ and between the two adjacent PS regions 724′, wherein the CSI region 737′ has a doping concentration higher than that of the N type epitaxial layer 702′.

Please refer to FIG. 7C for a preferred B2-B2′ cross-sectional view of FIG. 6 with a new and improved device structure, which is a cross-sectional view of the shielded gate electrode contact area. The SiC power device has a similar structure to FIG. 7B, except for the different gate structure in the gate trench 703″. In the present invention, a shielded gate electrode (SG, as illustrated) 707″ is formed in each of the gate trenches 703″ and vertically isolated from the N type epitaxial layer 702″ by a second gate oxide film (GOX2) 719″ on a bottom of the gate trench and laterally isolated from the N type epitaxial layer 702″ by a third gate oxide film (GOX3) 729″ on the gate trench sidewall, wherein the second gate oxide film 719″ has a thinner thickness than that of the third gate oxide film 729″, and furthermore, the shielded gate electrode 707″ is connected to a source metal 712″ through a trenched contact 733″.

Please refer to FIG. 7D for another preferred A2-A2′ cross-sectional view of FIG. 6 with a new and improved device structure. The SiC power device has a similar structure to FIG. 7B, except that the present invention further comprises an N type buffer source region 747′″ below the first and second source regions 711′″ and 717′″ with a doping concentration lower than that of the first and second source regions 711′″ and 717′″ to increase the source resistance for positive temperature coefficient improvement.

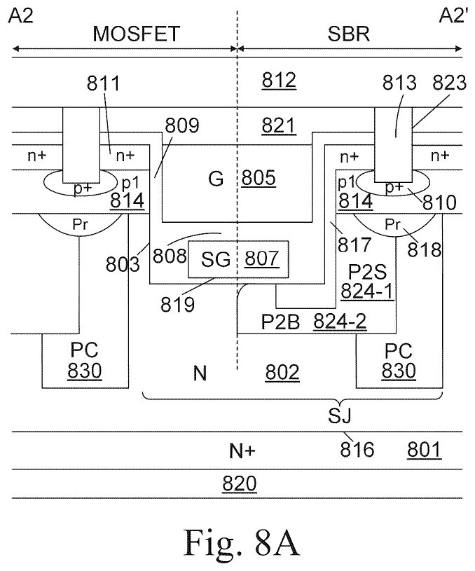

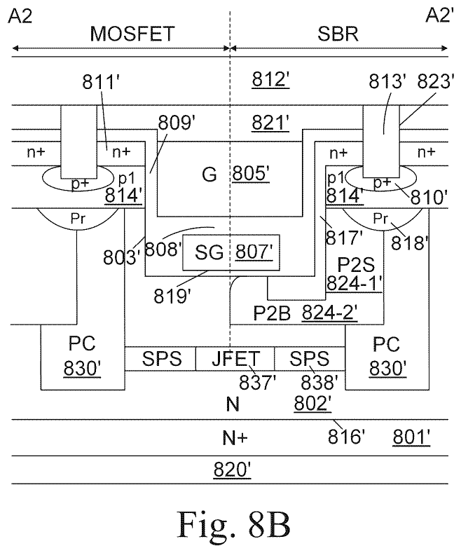

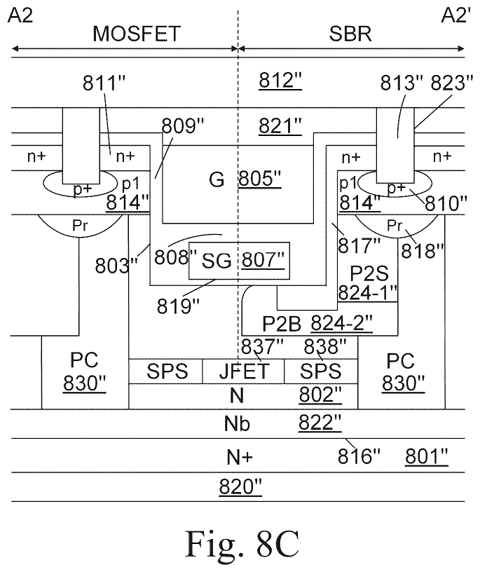

Please refer to FIG. 8A for another preferred A2-A2′ cross-sectional view of FIG. 6 with a new and improved device structure. The SiC power device has a similar structure to FIG. 7A, except that the the PS region surrounding the second gate trench sidewall (P2S, as illustrated) 824-1 has a doping concentration higher than that of the PS region surrounding the gate trench bottom (P2B, as illustrated) 824-2, and the present invention further comprises P column (PC, as illustrated) regions 830 of a second conductivity type formed adjoining bottom surfaces of the first and second p body regions 814, 824-1 and 824-2 above the N+ substrate 801. A super junction (SJ, as illustrated) structure is thus generated by the N type epitaxial layer 802 and the PC region 830.

Please refer to FIG. 8B for another preferred A2-A2′ cross-sectional view of FIG. 6 with a new and improved device structure. The SiC power device has a similar structure to FIG. 8A, except that the present invention further comprises two sidewall P-shield (SPS, as illustrated) regions 838′ of a second conductivity type facing each other horizontally adjoining the P column (PC, as illustrated) regions 830′ with a doping concentration higher than that of the PC regions 830′, and a Junction Field Effect Transistor (JFET, as illustrated) region 837′ of a first conductivity type is formed between the two SPS regions 838′ with a doping concentration higher than that of the N type epitaxial layer 802′.

Please refer to FIG. 8C for another preferred A2-A2′ cross-sectional view of FIG. 1 with a new and improved device structure. The SiC power device has a similar structure to FIG. 8B, except that the present invention further comprises an additional N buffer layer (Nb, as illustrated) 822″ with a resistivity Rb sandwiched between the N+ substrate 801″ and the PC regions 830″, wherein Rb is higher than a resistivity R of the N type epitaxial layer 802″.

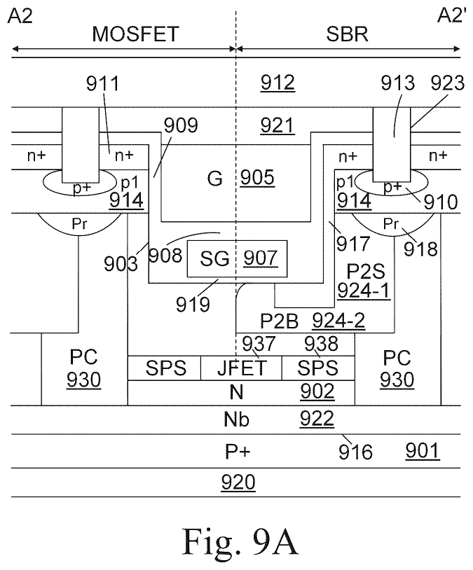

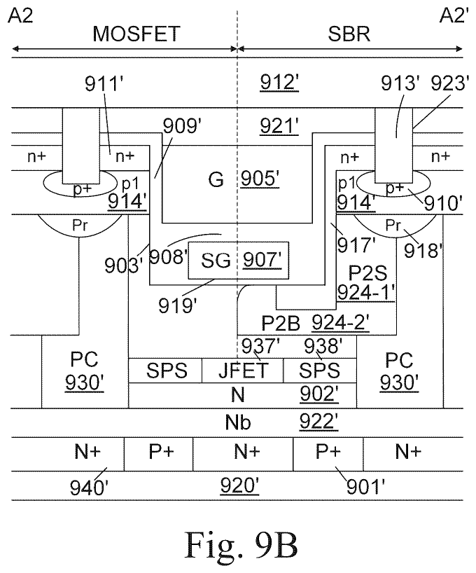

Please refer to FIG. 9A for another preferred A2-A2′ cross-sectional view of FIG. 6 with a new and improved device structure. The SiC power device has a similar structure to FIG. 8C, except for the different substrate. In this invention, the SiC power device is formed on a P+ substrate 901, and the N buffer layer (Nb, as illustrated) 922 sandwiched between the P+ substrate 901 and the PC regions 930 has a resistivity Rb lower than a resistivity R of the N type epitaxial layer 902.

Please refer to FIG. 9B for another preferred A2-A2′ cross-sectional view of FIG. 6 with a new and improved device structure. The SiC power device has a similar structure to FIG. 9A, except that, the SiC power device in FIG. 9B further comprises a plurality of heavily doped N+ regions 940′ in the P+ substrate 901′ to form a plurality of alternating P+ and N+ regions in the substrate.

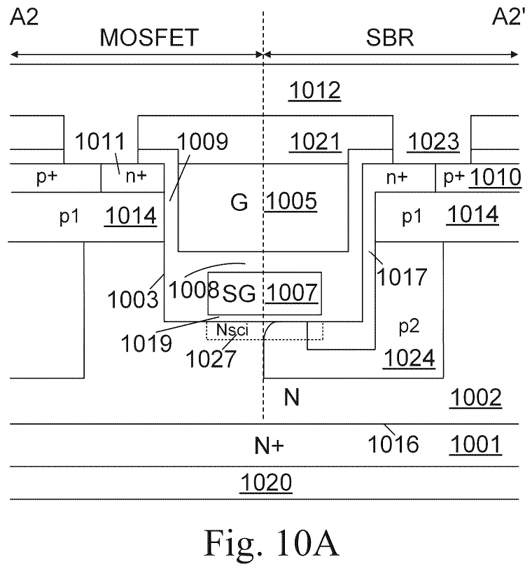

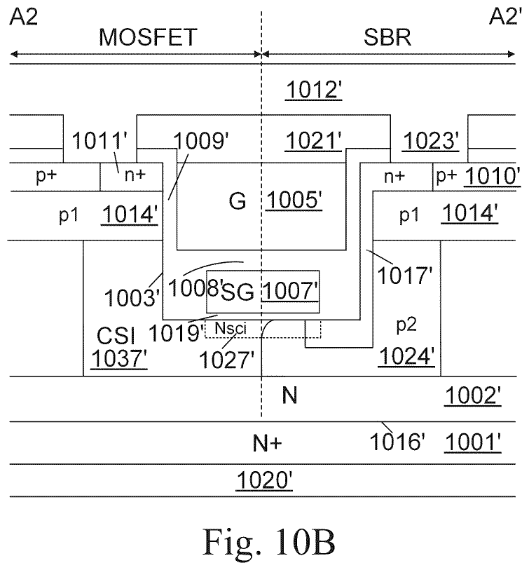

Please refer to FIG. 10A for another preferred A2-A2′ cross-sectional view of FIG. 6 with a new and improved device structure. The SiC power device has a similar structure to FIG. 7A, except that the p type gate oxide electric field reducing regions in FIG. 7A don't exist in the present invention, and the source contacts 1023 are planar contacts.

Please refer to FIG. 10B for another preferred A2-A2′ cross-sectional view of FIG. 6 with a new and improved device structure. The SiC power device has a similar structure to FIG. 10A, except that the present invention further comprises an N type current spreading implant (CSI, as illustrated) region 1037′ formed below a bottom of the gate trench 1003′ and between the two adjacent PS regions 1024′, wherein the CSI region 1037′ has a doping concentration higher than that of the N type epitaxial layer 1002′.

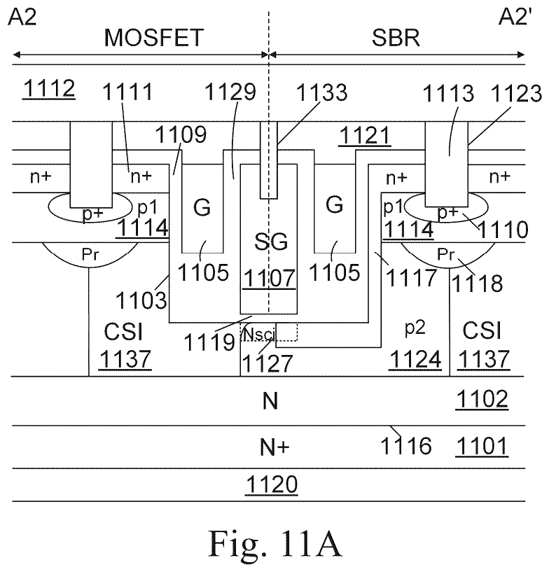

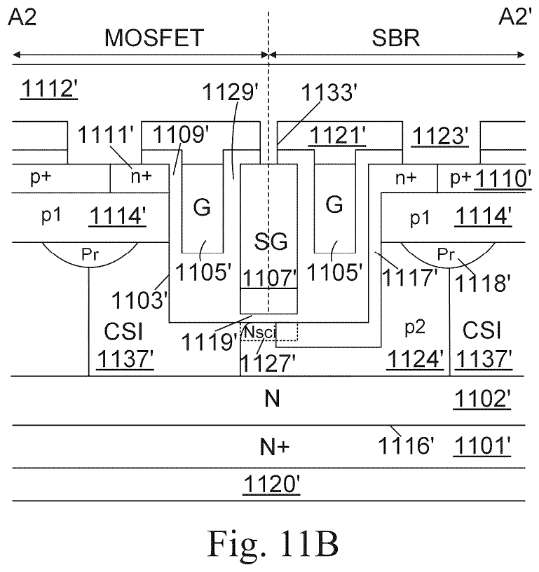

Please refer to FIG. 11A for another preferred A2-A2′ cross-sectional view of FIG. 6 with a new and improved device structure. The SiC power device has a similar structure to FIG. 7B, except for the different shielded gate structure in the gate trenches 1103. In the present invention, inside each of the gate trenches 1103, a shielded gate electrode (SG, as illustrated) 1107 is disposed in the middle as a second gate electrode and a pair of split gate electrodes (G, as illustrated) 1105 are disposed surrounding an upper portion of the shielded gate electrode 1107 as the first gate electrodes. The first gate electrodes 1105 are laterally isolated from the epitaxial layer with a first gate oxide (GOX1) 1109 of the SiC MOSFET on the first gate trench sidewall, and the shielded gate electrode 1107 is vertically isolated from the epitaxial layer with a second gate oxide 1119 on a bottom of the gate trench 1103, wherein the second gate oxide 1119 has a thickness less than that of the first gate oxide 1109. Moreover, another insulating film 1129 isolating the shielded gate electrode 1107 and the gate electrodes 1105 is covering on an upper portion of the shielded gate electrode 1107, wherein the insulating film 1129 is formed at the same time during growing the gate oxide 1109 in the manufacturing process. Furthermore, the shielded gate electrode 1107 is connected to a source metal 1112 through a trenched contact 1133.

Please refer to FIG. 11B for another preferred A2-A2′ cross-sectional view of FIG. 6 with a new and improved device structure. The SiC power device has a similar structure to FIG. 11A, except that the source contacts 1123′ and 1133′ in the present invention are planar contacts.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A silicon carbide (SiC) power device having a SiC MOSFET and a SiC super barrier rectifier (SBR) as a MOS channel diode (MCD) disposed in a gate trench of each unit cell comprising:
an epitaxial layer of a first conductivity type grown on a substrate;
a first channel region of said SiC MOSFET formed along a first gate trench sidewall of said gate trench, and a second channel region of said SiC SBR formed along a bottom region of said gate trench;
said SiC MOSFET further comprising:
a first body region of a second conductivity type having a first source region of said first conductivity type thereon;
said first channel region formed between said first body region and said first source region;
said SiC SBR further comprising:
a first P-shield (PS) region of said second conductivity type acting as a second body region, and a second source region of said first conductivity type;
said second body region and said second source region surrounding a second gate trench sidewall of said gate trench, and a portion of said bottom region of said gate trench adjacent to said second gate trench sidewall, wherein said second gate trench sidewall is opposite to said first gate trench sidewall;
said second channel region formed between said second body region and said second source region; and
said first and second body regions, and said first and second source regions being shorted to a source metal through source contacts.

2. The SiC power device of claim 1, further comprising:
a first gate electrode of said SiC MOSFET and a second gate electrode of said SiC SBR disposed in said gate trench side by side;
said first gate electrode laterally isolated from said epitaxial layer by a first gate oxide of said SiC MOSFET on said first gate trench sidewall, and said second gate electrode vertically isolated from said epitaxial layer by a second gate oxide of said SiC SBR on said bottom region of said gate trench, wherein said second gate oxide has a thickness less than that of said first gate oxide; and
said second gate electrode being shorted to a source metal through a gate contact of said SiC SBR.

3. The SiC power device of claim 2, wherein said first gate electrode vertically isolated from said epitaxial layer by a thick bottom oxide with a thickness greater than that of said first gate oxide.

4. The SiC power device of claim 1, further comprising:
a gate electrode disposed in an upper portion of said gate trench, and a shielded gate electrode disposed below said gate electrode and isolated from said gate electrode by an inter-poly oxide (IPO) layer;
said gate electrode acting as a first gate electrode laterally isolated from said epitaxial layer by a first gate oxide of said SiC MOSFET on said first gate trench sidewall, and said shielded gate electrode acting as a second gate electrode vertically isolated from said epitaxial layer by a second gate oxide of said SiC SBR on said bottom region of said gate trench, wherein said second gate oxide has a thickness less than that of said first gate oxide; and
said shielded gate electrode shorted to said source metal through a shielded gate contact of said SiC SBR.

5. The SiC power device of claim 1, further comprising;
a shielded gate electrode disposed in a middle of said gate trench, and a pair of split gate electrodes acting as a first gate electrodes disposed surrounding an upper portion of said shielded gate electrode.
said first gate electrodes laterally isolated from said epitaxial layer by a first gate oxide of said SiC MOSFET on said first gate trench sidewall, and said shielded gate electrode acting as a second gate electrode vertically isolated from said epitaxial layer with a second gate oxide of said SiC SBR on said bottom region of said gate trench, wherein said second gate oxide has a thickness less than that of said first gate oxide; and
said shielded gate electrode shorted to said source metal through a shielded gate contact of said SiC SBR.

6. The SiC power device of claim 1, further comprising a short channel implant (SCI) region of said first conductivity type formed below said bottom region of said gate trench surrounding said second channel region, wherein said SCI region has a doping concentration higher than that of said epitaxial layer.

7. The SiC power device of claim 1, wherein said second channel region has a channel length shorter than that of said first channel region.

8. The SiC power device of claim 1, wherein said second body region has a doping concentration lower than that of said first body region.

9. The SiC power device of claim 1, further comprising a second P-shield (PS) region of said second conductivity type, adjoining a lower surface of said first body region and being spaced apart from said gate trench.

10. The SiC power device of claim 1, wherein said first PS region surrounding said second gate trench sidewall has a doping concentration higher than that of said PS region surrounding said bottom region of said gate trench.

11. The SiC power device of claim 1, further comprising a third PS region of said second conductivity type adjacent to said second source region, wherein said third P-shield region has a doping concentration higher than that of said first PS region.

12. The SiC power device of claim 1, further comprising a buffer source region of said first conductivity type below said first and second source regions with a doping concentration lower than that of said first and second source regions.

13. The SiC power device of claim 1, further comprising a current spreading implant (CSI) region of said first conductivity type between the two adjacent said PS regions, wherein said CSI region has a doping concentration higher than that of said epitaxial layer.

14. The SiC power device of claim 1, further comprising a super junction (SJ) structure comprising a P column (PC) region of said second conductivity type disposed on a buffer layer of said first conductivity type with a resistivity Rb sandwiched between said substrate and said epitaxial layer, and said PC region is connected to said first body region.

15. The SiC power device of claim 14, wherein said substrate has said first conductivity type and said epitaxial layer comprises a single epitaxial layer having an uniform doping concentration with a resistivity R, and said R<said Rb.

16. The SiC power device of claim 14, wherein said substrate has said second conductivity type and said epitaxial layer comprises a single epitaxial layer having an uniform doping concentration with a resistivity R, and said R>said Rb.

17. The SiC power device of claim 16, further comprising a plurality of heavily doped regions of said first conductivity type in said substrate to form a plurality of alternating P+ and N+ regions in said substrate.

18. The SiC power device of claim 14, further comprising at least two sidewall P-shield (SPS) regions of said second conductivity type facing each other with a doping concentration higher than a doping concentration of said PC region, adjoining said PC region and being vertically spaced apart from said buffer layer and said second body region, and a Junction Field Effect Transistor (JFET) region of said first conductivity type formed between said two SPS regions with a doping concentration higher than that of said epitaxial layer.

19. The SiC power device of claim 1, wherein said source contacts are trenched contacts.

20. The SiC power device of claim 1, wherein said source contacts are planar contacts.
